(19) United States
(12) Patent Application Publication
(10) Pub. No.: US 2025/0298099 A1
(43) Pub. Date: Sep. 25, 2025

(54) METHOD AND SYSTEM FOR MAGNETIC FIELD MAPPING

(71) Applicant: INVENSENSE, INC, San Jose, CA (US)

(72) Inventors: Gennadii Berkovich, Calgary (CA); Dmitry Churikov, Calgary (CA)

(73) Assignee: INVENSENSE, INC, San Jose, CA (US)

(21) Appl. No.: 19/079,396

(22) Filed: Mar. 13, 2025

Related U.S. Application Data
(60) Provisional application No. 63/568,198, filed on Mar. 21, 2024.

(51) Int. Cl. G01R 33/10; G01R 33/00

(52) U.S. Cl. CPC G01R 33/10; G01R 33/0017

(57) ABSTRACT

Systems and methods are disclosed for building a magnetic map of an indoor area. An initial magnetic map of the area is built from Earth's magnetic field measurements obtained from at least one platform and is based at least in part on an initial calibration of the magnetometer. At least one recalibration condition is identified for the area based at least in part on orientations and positions of the at least one platform. The magnetometer is recalibrated based at least in part on the Earth's magnetic field measurements obtained for each recalibration condition to update biases for the magnetometer. A rebuilt magnetic map is then generated for the area using the updated biases for the magnetometer.

### CROSS-REFERENCE TO RELATED APPLICATIONS

This application claims priority from and benefit of U.S. Provisional Patent Application Ser. No. 63/568,198, filed Mar. 21, 2024, which is entitled “Mapping Magnetic Field of Indoor Area,” is assigned to the assignee hereof, and is incorporated by reference in its entirety.

### FIELD OF THE PRESENT DISCLOSURE

The present disclosure relates to positioning of people, vehicles and goods within indoor environments. More specifically, systems and methods are provided for creating magnetic maps that may be used for navigation.

### BACKGROUND

Particularly in the context of mobile or portable electronic devices, it is desirable to provide location awareness capabilities. An expanding variety of technologies have been developed to provide a device with information about its location, allowing it to selectively deliver information based on its location context or to otherwise adapt its operation. Common examples include navigation aids that may be used to guide a user to a desired destination, dispatch of emergency services, social networking applications that may inform the user about others that may be in proximity, targeted advertising schemes that may provide information relative to the user's location or tracking utilities that may provide real time information about a user's whereabouts.

In some cases, a portable device may have position determination capabilities in the form of a Global Navigation Satellite System (GNSS) that, under the proper conditions, may provide precise information about the geographic location of the device. However, GNSS performance may be subject to degradation when visibility of the satellites is reduced. For example, use of GNSS in an indoor environment may lengthen the time needed to obtain the necessary fix on the satellites or may prevent it entirely. Common alternatives or supplements to GNSS include self-contained motion sensors, such as low cost Micro Electro-Mechanical Systems (MEMS) inertial sensors, barometers and magnetometers. Reference-based techniques, such as GNSS, and self-contained sensors can be integrated to provide promising positioning results in most outdoor environments. However, some mass market applications require seamless positioning capabilities in all kinds of environments such as malls, offices or underground parking lots. In the absence of GNSS signals in indoor environments, an Inertial Navigation System (INS) may be used by employing techniques such as dead reckoning to help determine position. Nevertheless, sensor-based techniques may fail to provide adequate performance by themselves, particularly over longer durations due to significant performance degradation from accumulating sensor drifts and bias. As such, positioning technologies relying solely on motion sensors may not satisfy all requirements for seamless indoor and outdoor navigation applications. As a result, alternative positioning techniques that can provide strong coverage in areas where access to other reference-based positioning is degraded or denied have been developed.

One class of techniques is known as “fingerprinting,” and relies on recording patterns of electromagnetic wireless signals at known locations within an area for which position information may be desired. When a device subsequently measures a pattern of received signals that is correlated with a known location, that location may be used to determine the position of the device and/or to aid another positioning technique, such as through integration with the INS techniques noted above. With particular regard to this disclosure, environmental signals in the form of magnetic fields may be used as the basis for creating a fingerprint map. Magnetic fingerprint-based positioning offers a number of compelling advantages because it is infrastructure-free and benefits from the long-term stability of magnetic fields inside a building.

As noted, a fingerprint database must be built to correlate magnetic signal patterns with known locations. Unfortunately, building these databases is a time-consuming and resource-intensive procedure. Generally, one or more surveys are performed so that magnetometer readings are collected at desired positions inside a building at a useful resolution, such as by taking readings at locations separated by a given distance, for example, 1 or 2 meters, and then estimating the magnetic field patterns in those positions by processing magnetometer readings. Such systematic surveys of magnetic fields in a building may be performed by moving along predetermined routes with portable devices to record the measurements.

However, magnetometer measurements are subject to hard- and soft-iron distortions induced by an environment platform, e.g., a PCB of the device carrying the magnetometer. Therefore, a calibration process of a magnetometer is required to achieve desired accuracy of measurement of geomagnetic fields. Several approaches have been proposed to provide magnetometer calibration. Calibration algorithms usually include rotating the magnetometer in multiple directions, acquiring uncalibrated magnetometer measurements during the rotation, and estimating the magnetometer bias and possibly other parameters (like scale-misalignment matrix)) by fitting a sphere or an ellipsoid to the collected magnetometer measurements.

Calibration algorithms often rely on assumption of constancy of geomagnetic field during the calibration process or/and an assumption of known strength of geomagnetic field. Both assumptions may not be satisfied in case of indoor positioning. For example, Earth's magnetic field indoors is distorted by ferromagnetic elements in the building structure and is not known in advance. Involuntary change of center of rotation of magnetometer indoors results in violation of condition of constancy of magnetic field during calibration. Further a platform carrying the magnetometer sometimes cannot be rotated properly in multiple directions because of limitations of the platform's constructure.

As the magnetometer bias can change over time, the calibration process should be repeated from time to time that complicates mapping of magnetic field. One approach is to calibrate the magnetometer outdoors where Earth's magnetic field is constant but this cannot be implemented in dense urban areas and is inconvenient for surveyors of large venues. As a result, known methods of calibration the magnetometer indoors cannot guarantee achieving high accuracy of calibration. Earth's magnetic field indoors usually variates within a relatively narrow range, therefore even a calibration error of a few micro-Tesla can negatively impact on magnetic-based indoor positioning.

Accordingly, the techniques of this disclosure represent improvements in the quality of mapping magnetic field by improving accuracy of magnetometer calibration. Further, these techniques facilitate and expedite the process of mapping magnetic field indoors and make it easier and faster for surveyors. These and other benefits are described in the following materials.

### SUMMARY

This disclosure includes a method for building a magnetic map of an indoor area. The area comprises a plurality of positions and the magnetic map comprises Earth's magnetic field values for the positions. The method may involve building an initial magnetic map of the area by traversing the area with at least one platform having an associated magnetometer and obtaining Earth's magnetic field measurements with the magnetometer at determined positions and orientations of the at least one platform within the area, wherein the initial magnetic map is built based at least in part on an initial calibration of the magnetometer, identifying at least one recalibration condition for the area based at least in part on orientations and positions of the at least one platform, recalibrating the magnetometer based at least in part on the Earth's magnetic field measurements obtained for each recalibration condition, wherein biases for the magnetometer are updated and generating a rebuilt magnetic map for the area using the updated biases for the magnetometer.

This disclosure also includes a system for building a magnetic map of an indoor area, wherein the area comprises a plurality of positions and wherein the magnetic map comprises Earth's magnetic field values for the positions. The system may have at least one platform having an associated magnetometer for traversing the area to obtain Earth's magnetic field measurements at determined positions and orientations of the at least one platform within the area, remote processing resources configured to: i) build an initial magnetic map of the area, wherein the initial magnetic map is built based at least in part on an initial calibration of the magnetometer, ii) identify at least one recalibration condition for the area based at least in part on orientations and positions of the at least one platform, iii) recalibrate the magnetometer based at least in part on the Earth's magnetic field measurements obtained for each recalibration condition, wherein biases for the magnetometer are updated and iv) generate a rebuilt magnetic map for the area using the updated biases for the magnetometer.

This disclosure also includes a server for building a magnetic map of an indoor area, wherein the area comprises a plurality of positions and wherein the magnetic map comprises Earth's magnetic field values for the positions. The server may have processing resources configured to: a) build an initial magnetic map of the area from Earth's magnetic field measurements obtained from at least one platform having an associated magnetometer that traverses the area at determined positions and orientations, wherein the initial magnetic map is built based at least in part on an initial calibration of the magnetometer, b) identify at least one recalibration condition for the area based at least in part on orientations and positions of the at least one platform, c) recalibrate the magnetometer based at least in part on the Earth's magnetic field measurements obtained for each recalibration condition to update biases for the magnetometer and d) generate a rebuilt magnetic map for the area using the updated biases for the magnetometer.

### BRIEF DESCRIPTION OF THE DRAWINGS

FIG. 1 is a schematic diagram of magnetic field mapping system according to an embodiment.

FIG. 2 is a flowchart showing a routine for building a magnetic field map using recalibration conditions according to an embodiment.

FIG. 3 is a graphical representation of one example of a recalibration condition according to an embodiment.

FIGS. 4a and 4b schematically depict a comparison of paths with respect to identifying a recalibration condition according to an embodiment.

FIG. 5 is a graphical representation indicating the updating of biases of a magnetometer according to an embodiment.

FIGS. 6a and 6b graphically depict effect of improvement in accuracy of magnetometer bias determination according to an embodiment.

FIG. 7 is a flow chart showing examples of possible variants of the method.

FIG. 8 is a graphical representation of creating paths to provide recalibration conditions according to an embodiment.

### DETAILED DESCRIPTION

At the outset, it is to be understood that this disclosure is not limited to particularly exemplified materials, architectures, routines, methods or structures as such may vary. Thus, although a number of such options, similar or equivalent to those described herein, can be used in the practice or embodiments of this disclosure, the preferred materials and methods are described herein.

It is also to be understood that the terminology used herein is for the purpose of describing particular embodiments of this disclosure only and is not intended to be limiting.

The detailed description set forth below in connection with the appended drawings is intended as a description of exemplary embodiments of the present disclosure and is not intended to represent the only exemplary embodiments in which the present disclosure can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the specification. It will be apparent to those skilled in the art that the exemplary embodiments of the specification may be practiced without these specific details. In some instances, well known structures and devices are shown in block diagram form in order to avoid obscuring the novelty of the exemplary embodiments presented herein.

For purposes of convenience and clarity only, directional terms, such as top, bottom, left, right, up, down, over, above, below, beneath, rear, back, and front, may be used with respect to the accompanying drawings or chip embodiments. These and similar directional terms should not be construed to limit the scope of the disclosure in any manner.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present.

Some portions of the detailed descriptions which follow are presented in terms of procedures, logic blocks, processing and other symbolic representations of operations on data bits within a computer memory. These descriptions and representations are the means used by those skilled in the data processing arts to most effectively convey the substance of their work to others skilled in the art. In the present application, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and converts data represented as physical (electronic) quantities within the computer system's registers and memories into other data similarly represented as physical quantities within the computer system memories or registers or other such information storage, transmission or display devices.

Embodiments described herein may be discussed in the general context of processor-executable instructions residing on some form of non-transitory processor-readable medium, such as program modules, executed by one or more computers or other devices. Generally, program modules include routines, programs, objects, components, data structures, etc., that perform particular tasks or implement particular abstract data types. The functionality of the program modules may be combined or distributed as desired in various embodiments.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the exemplary wireless communications devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

The non-transitory processor-readable storage medium may comprise random access memory (RAM) such as synchronous dynamic random access memory (SDRAM), read only memory (ROM), non-volatile random access memory (NVRAM), electrically erasable programmable read-only memory (EEPROM), FLASH memory, other known storage media, and the like. The techniques additionally, or alternatively, may be realized at least in part by a processor-readable communication medium that carries or communicates code in the form of instructions or data structures and that can be accessed, read, and/or executed by a computer or other processor. For example, a carrier wave may be employed to carry computer-readable electronic data such as those used in transmitting and receiving electronic mail or in accessing a network such as the Internet or a local area network (LAN). Of course, many modifications may be made to this configuration without departing from the scope or spirit of the claimed subject matter.

The various illustrative logical blocks, modules, circuits and instructions described in connection with the embodiments disclosed herein may be executed by one or more processors, such as one or more motion processing units (MPUs), sensor processing units (SPUs), digital signal processors (DSPs), general purpose microprocessors, application specific integrated circuits (ASICs), application specific instruction set processors (ASIPs), field programmable gate arrays (FPGAs), or other equivalent integrated or discrete logic circuitry. The term “processor,” as used herein may refer to any of the foregoing structure or any other structure suitable for implementation of the techniques described herein. In addition, in some aspects, the functionality described herein may be provided within dedicated software modules or hardware modules configured as described herein. Also, the techniques could be fully implemented in one or more circuits or logic elements. A general purpose processor may be a microprocessor, but in the alternative, the processor may be any conventional processor, controller, microcontroller, or state machine. A processor may also be implemented as a combination of computing devices, e.g., a combination of an SPU and a microprocessor, a plurality of microprocessors, one or more microprocessors in conjunction with an SPU core, or any other such configuration.

Unless defined otherwise, all technical and scientific terms used herein have the same meaning as commonly understood by one having ordinary skill in the art to which the disclosure pertains.

Finally, as used in this specification and the appended claims, the singular forms “a, “an” and “the” include plural referents unless the content clearly dictates otherwise.

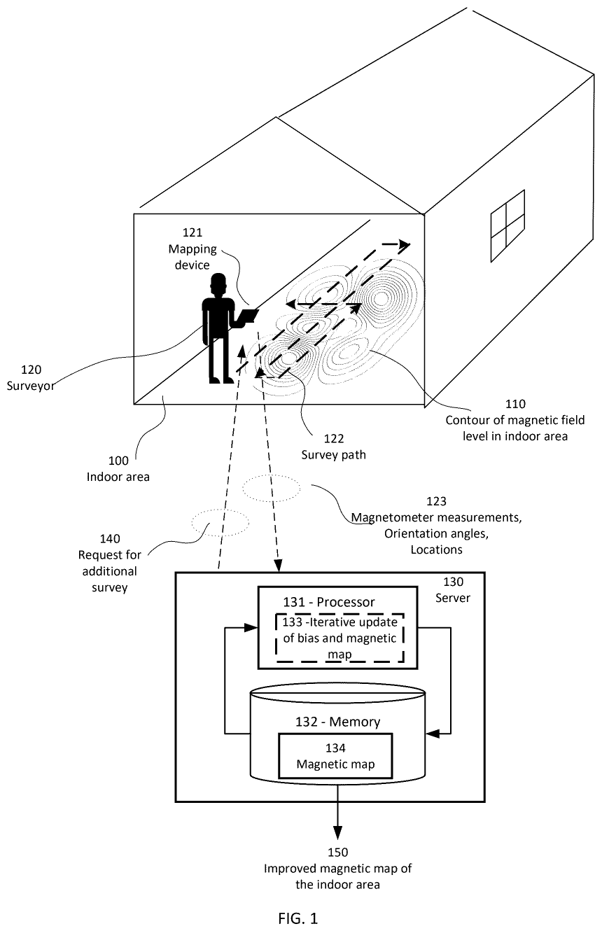

To help illustrate the aspects of this disclosure, a representative example of a possible configuration of the system for mapping magnetic field of an indoor area is schematically depicted in FIG. 1. The figure shows an indoor area 100. Variations of Earth's magnetic field in the area 100 are illustrated by contour lines 110 of magnetic field level.

Surveyor 120 holding a mapping device 121 walks along survey path 122. The mapping device 121 may be equipped with sensors like a magnetometer, inertial, pressure sensor (barometer), camera, LiDAR, wireless ranging modules like for example, UWB-based, and other sensors. The mapping device may be also equipped with a processor and communication modules. The equipment of the mapping device allows taking measurements of Earth's magnetic field 110 while walking along the path 121, determining location and orientation of the mapping device, and sending mapped data 123 including Earth's magnetometer measurements, device orientation angles, and location of the device 121 to a server 130.

The server 130 comprises at least one processor 131 and at least one memory 132. The processor 131 is configured to implement operations 133 for iterative update of magnetometer biases and magnetic map, which are described in detail below. The memory 132 stores magnetic map 134. The cyclical connections between the processor 131 and the memory 132 represent the iterative update of the magnetic map as discussed herein.

Upon results of the processing, the sever 130 may send to the surveyor 120 a request 140 for an additional survey, which will be described below.

As such, the improved magnetic map 150 can be sent to the users to be used for magnetic-based positioning in the area 100.

The example of FIG. 1 serves just as an illustration of the proposed ideas. Many different implementations are possible. For example, not only a human surveyor 120 can carry a mapping device like shown in FIG. 1. The surveying platform can be any platform conveying the magnetometer, like a human, a vehicle, a robot, an indoor drone, etc.

The mapping device can be any portable device equipped with a magnetometer and other relevant sensors like, for example, a smartphone, a smartwatch, a tablet, a custom device equipped with the sensors, etc. One approach to collecting the necessary magnetic data that seeks to reduce or eliminate the need for dedicated surveys is based on use of everyday activity of a plurality of persons inside a building undergoing normal behavior, such as shopping in a retail mall or progressing between gates and other locations in an airport. Given the widespread adoption of capable portable devices, such as smart phones, a suitable device associated with each person may passively record multiple magnetic field measurements without requiring any change in behavior. These methods are typically known as crowdsourcing and represent an opportunity to acquire the necessary data without performing special surveys of the building. Alternatively, or additionally, the functions of the mapping device can be distributed between different components of a platform. For example, in a case of the robot-based mapping, magnetometer measurements can be supplemented by locations obtained from robot's lidar-based positioning system.

Instead of following the predetermined path 122, surveyors can determine paths by their own, such implementing crowdsource-based mapping. Both types of mapping, regular and crowdsourcing, may be combined when surveying different parts of the indoor area. Only one surveyor 120 and one survey path 122 are shown as an example, but a plurality or surveyors and a plurality of paths can be used as well for mapping of indoor area 100.

In some embodiments, processing 133 is not necessarily implemented on a remote processor 131 of server 130 but can be distributed between the processor 131 and a mapping device 121 or several devices in case of multiple surveyors. In one embodiment for example the mapping device 121 may send sensor data to the remote processor 131 that may be configured to determine location and orientation angles of the mapping device, whereas in another embodiment all these operations may be implemented on the mapping device 121.

To support the data interchange between the server 130 and surveying platform 120 or several platforms in case of multiple surveyors, the platforms and server may communicate through a wireless or cellular network. Any suitable protocol, including cellular-based and wireless local area network (WLAN) technologies such as Universal Terrestrial Radio Access (UTRA), Code Division Multiple Access (CDMA) networks, Global System for Portable Communications (GSM), the Institute of Electrical and Electronics Engineers (IEEE) 802.16 (WiMAX), Long Term Evolution (LTE), IEEE 802.11 (WiFi™) and others may be employed. Communication may be direct or indirect, such as through multiple interconnected networks. As will be appreciated, a variety of systems, components, and network configurations, topologies and infrastructures, such as client/server, peer-to-peer, or hybrid architectures, may be employed to support distributed computing environments. For example, computing systems can be connected together by wired or wireless systems, by local networks or widely distributed networks. Currently, many networks are coupled to the Internet, which provides an infrastructure for widely distributed computing and encompasses many different networks, though any network infrastructure can be used for exemplary communications made incident to the techniques as described in various embodiments.

Any or all of the functions described with respect to mapping device 121 and server 130 may be performed by any number of discrete devices in communication with each other, or may be performed by device 121 itself in other suitable system architectures. Accordingly, it should be appreciated that any suitable division of processing resources may be employed whether within one device or among a plurality of devices. Further, aspects implemented in software may include but are not limited to, application software, firmware, resident software, microcode, etc., and may take the form of a computer program product accessible from a computer-usable or computer-readable medium providing program code for use by or in connection with a computer or any instruction execution system, such as a host processor, a sensor processor, a server processor, a dedicated processor or any other processing resources of device 121, server 130 or other remote processing resources, or may be implemented using any desired combination of software, hardware and firmware.

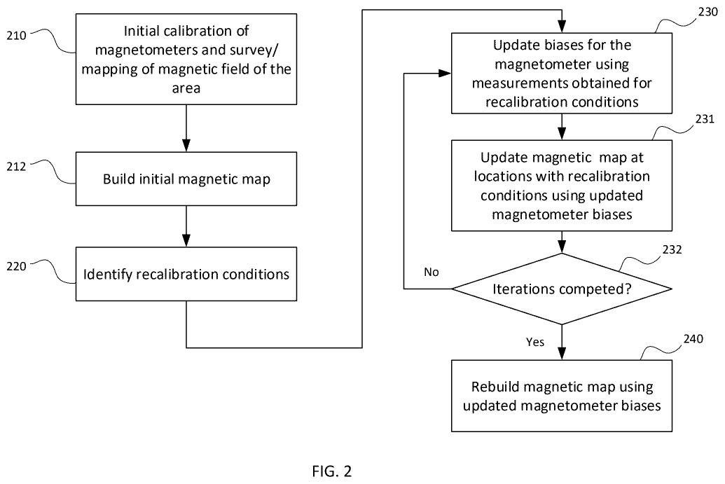

One representative process for mapping magnetic field in an indoor area involves multiple operations as schematically indicated in FIG. 2. First, at step 210, initial calibration of a magnetometer of mapping device is performed and the indoor area 100 is surveyed/mapped. As noted above, this initial mapping may be of a regular type, i.e., by following predetermined paths, or crowdsourcing-based, or a combination of those types of survey/mapping. The initial calibration may be performed before the survey in a mapping device 121 by using the approach mentioned above, i.e., based on rotation of the magnetometer in multiple directions, which as noted, might be less accurate than desired. Using raw (uncalibrated) magnetometer measurements for different directions, calibration parameters such as magnetometer biases may be determined as noted above. Then, the magnetometer may be calibrated by applying the calibrated parameters to raw magnetometer measurements such as by subtracting the magnetometer biases from the raw magnetometer measurements. Mapped data is output to server 130 through any available communication channel, such as those described above.

In some embodiments, survey/mapping can be performed before the initial calibration, and the calibration can be implemented offline after the survey. This approach may be more convenient, for example, for crowdsourced-based survey, which may be implemented by a plurality of unqualified users as it allows users not to bother about magnetometer calibration. As one illustration, commonly-owned U.S. Pat. No. 10,914,793, which is hereby incorporated by reference in its entirety, details suitable techniques that may be used for the offline post-survey initial calibration. In one aspect, server 130 may perform the offline calibration of mapped data for these embodiments.

At step 212, server 130 builds an initial magnetic map using the data obtained during the survey/mapping with initially calibrated magnetometer as was described for step 210. Different approaches can be used for building the initial magnetic map, for example, commonly-owned U.S. Pat. No. 11,035,915, which is hereby incorporated by reference in its entirety, provides suitable techniques.

Once the initial magnetic map is built, at least one recalibration condition is identified in magnetic map at step 220 for a location that exhibits the characteristics by meeting predetermined constraints/conditions. This step and further steps will be described in detail below.

Next steps 230 and 231 are iterated depending on the number of recalibration conditions identified. First, the recalibration conditions are used for updating the magnetometer biases at step 230 based on the Earth's magnetic field measurements obtained for the recalibration conditions and using magnetic field map for recalibration conditions estimated on previous iteration and using previous value of magnetometer biases. Second, at step 231 the magnetic map is updated in at the locations associated with the identified recalibration conditions using magnetometer measurements with newly updated magnetometer biases. Both steps 230 and 231 are repeated several times with respect to identified recalibration conditions until a sufficient convergence is achieved so that finishing the iterations is satisfied at step 232.

Finally, the magnetic map 134 is totally rebuilt using finally determined magnetometer bias at step 240. Again, different approaches can be used for this purpose, for example, the map building techniques disclosed in U.S. Pat. No. 11,035,915 as incorporated above.

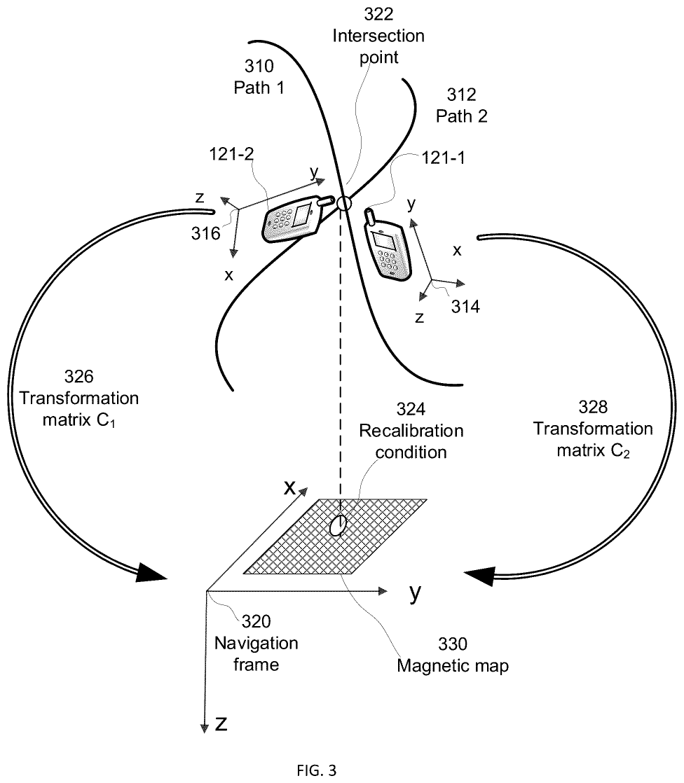

Identification of the recalibration conditions per step 220 may depend on distance and angular orientation characteristics of mapping device 121 as schematically illustrated in FIG. 3. As shown, two paths 310 and 312 represent the trajectory of mapping device 121 during survey of indoor area 100. In the figure, both paths have an intersection point 322, i.e., a mutual point where coordinates of the paths are the same when traversed at different times. At this intersection point, mapping device 121 has the same location, but different orientations denoted as 121-1 for the device on path 1 (310) and 121-2 for the device on path 2 (312). The body or device frame of mapping device is denoted as 314 for the device on path 1 (310) and 316 for the device on path 2 (312).

For clarity, a standard definition of the coordinate system may be employed for the sensors of portable devices, including the magnetometer, relative to the device's screen, indicated by coordinate axes 314 and 316 as shown. For the purposes of this example, the body frame corresponds to the X axis being horizontal and pointing to the right along the short dimension of the body, the Y axis is vertical and points up along the long dimension of the body, and the Z axis points toward the outside of the screen. It is contemplated that any other definitions of body frame can be used for the application of the method, system, and apparatus described herein.

The magnetic map provides correlations between Earth's magnetic field values and positions. For example, the magnetic map can be considered as a database, every record of which can contain a 3D vector of Earth's magnetic field at a certain position. The positions in the magnetic map can be in any suitable coordinate frame, for example, a Cartesian frame like a global frame (ECEF) or a local frame (ENU or NED), or a geodetic (Lat/Lon) coordinate system. One example of a magnetic map in NED frame 320 is depicted in FIG. 3, wherein the positive X-axis points North (N), the positive Y-axis points East (E), and the positive Z-axis points Downward (D). An example of magnetic map is shown as a rectangle area 330 in the horizontal plane; however, the map can be of a different shape. A grid that fills area 330 illustrates a possible structure of the magnetic map: each cell of the grid features a certain position and contains the 3D vector of magnetic field possibly together with covariance and other information. The magnetic map 330 in FIG. 3 is shown as a single layer, but the map can also contain several layers each for different heights or for different floors. For the purposes of clarity in this illustration, the magnetic map may be defined in the NED frame, which may also be referred to as a navigation frame, but in other embodiments, other suitable frames or systems may be employed and transformed as desired.

As the magnetometer measurements and the magnetic map values are in different frames, the magnetometer measurements may be transformed from the body (device) frame such as in frames 314 and 316 to a mutual frame of magnetic map 320 as above, such as the NED navigation frame in this context. As commonly known, transformation between frames can be performed by transformation matrices. In FIG. 3 the transformation matrixes are denoted as C₁ (326), which transforms magnetometer measurements from body frame 316 to navigation frame 320, and as C₂ (328), which transforms magnetometer measurements from body frame 314 to the same mutual navigation frame 320.

Location 324 in magnetic map 330 is an example of a recalibration condition that satisfies characteristics regarding distance and orientation: (1) it corresponds to the intersection point of at least two paths of the surveyor (like intersection point 322 of path 310 and path 312), which in this example results in each location being the same, and (2) orientations of mapping device 121 at the intersection point are sufficiently different. Although this recalibration condition results from intersection of paths, another example involves a turn of the path at a given location that causes a change of direction and therefore orientation of mapping device 121. It should be appreciated that even when paths intersect or when a path turns, magnetic field measurements may not be recorded at the exact instant of crossing or turning. Accordingly, techniques of this disclosure allow a recalibration condition to be identified when the distance between the locations when the magnetic field measurements are recorded is within a suitable threshold. Similarly, as detailed below, a second characteristic for identifying the recalibration condition is whether there is sufficient difference in orientation of mapping device 121 when the magnetic field measurements are made. This second condition may mean difference of at least one of attitude angles between the transformation matrixes at a candidate location of the magnetic map exceeding a suitable threshold of angular deviation. Examples of a quantitative measurement of the difference in orientation are discussed below.

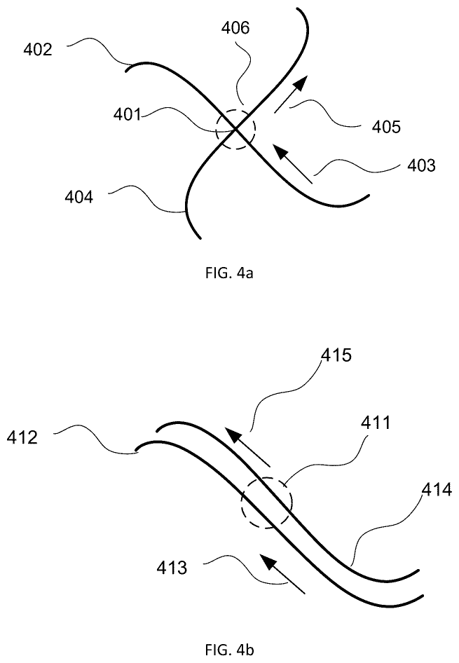

With respect to identifying a recalibration condition based on locations being within a suitable threshold when different magnetic field measurements are recorded, it will be appreciated that several approaches can be used. For example, the intersection point may be found by the Newton-Raphson method. For the discrete data, a spline or other kind of approximation may be applied. Another approach is to use pairwise comparison of coordinates of the data points together with defining a threshold distance to determine when two points are considered to be sufficiently close to each other. The latter approach is illustrated by FIG. 4a that shows two crossing paths, respectively 402 and 404, and directions of surveyor's movement along the paths, respectively 403 and 405. Intersection point 401 of paths 402 and 404 is inside circle 406, the radius of which can be an illustration of the mentioned threshold distance. All dimensions in FIG. 4 are given entirely as an illustration and do not limit any particular implementation of the proposed method. Further, interpolation can be applied such as after identifying close pairs of points to interpolate between them to estimate the further intersection point more accurately. One more possibility is iterative refinement of estimated intersection point using iterative methods like Newton-Raphson.

The second characteristic of sufficient difference in orientation, or angular deviation exceeding a suitable threshold, is also illustrated schematically in FIG. 4. Notably, FIG. 4a illustrates a case of a significant difference of device orientation angles, wherein the paths 402 and 404 intersect each other at 90°. Therefore, the point 401 can be considered as having the requisite characteristics and be identified as a recalibration condition to be used in further steps of the proposed method.

As a counter example, FIG. 4b shows the case in which orientation of the device is not sufficiently different. The figure shows two almost parallel paths 412 and 414 and direction of a surveyor's movement along these paths, 413 and 415 respectively. Although the paths may be considered to be close to each other, for example, measurements may be taken within circle 411 which denotes a suitable threshold distance, the orientations of mapping device are essentially the same, and therefore, the characteristic of angular deviation in orientation is not met and a recalibration condition is not identified.

Further aspects of the required angular deviation in orientation may be assed quantitatively. For this purpose, the following illustration represents one suitable technique although it should be appreciated that other methods may also be employed as desired. This illustration utilizes the following definitions:
K_{loc} is number of recalibration conditions,
Nₖ is number of paths associated with the recalibration condition k, k=1, . . . , K_{loc}, N=Σₖ₌₁^{K}^{_{loc}} Nₖ is total number of passes/trajectories associated with all recalibration conditions,
Fₖ is magnetic field map for location k in navigation frame,
Cₖᵢ is transformation matrix from body frame to navigation frame for path i coming through location k, i=1, . . . , Nₖ,
zₖᵢ is Earth's magnetometer measurement in body frame for path i coming through location k,
b is magnetometer bias,
l is 3×3 identity matrix.

A measure of difference of orientation angels for the second condition of the recalibration conditions can be formulated with the help of the following 3×3 matrix according to Equation (1):

$$A = \frac{1}{N} {\sum }_{k = 1}^{{K}_{loc}} \frac{1}{{N}_{k} - 1} {\sum }_{i = 1}^{{N}_{k}} {{\sum }_{j = 1}^{{N}_{k}}}_{j \neq i} {C}_{ki}^{T} {C}_{kj} \qquad ( 1 )$$

Matrix A may be interpreted as an averaged combination of transformation matrixes (like 326 and 328) at all intersection points and may be computed for all identified recalibration conditions or for a part of them.
One example that meets the deviation in angular orientation occurs when the determinant shown in Equation (2) is non-zero:

$$det ( A - I ) \neq 0 \qquad ( 2 )$$

An equivalent form of this characteristic is that every eigenvalue of matrix A must not be equal one, i.e., as per Equation (3):

$${λ}_{i} = eig ( A ) \neq 1 \qquad ( 3 )$$

Examples of FIG. 4 illustrate the measure of difference of orientation angles for the second condition of the recalibration conditions. Cases with intersections of paths as shown in FIG. 4a meet Equations (2) and (3) and can be used as recalibration conditions in further steps of the proposed method. In contrast, for the cases of parallel paths as shown in FIG. 4b, transformation matrixes of Equation (1), Cₖⱼ and Cₖᵢ respectively, are the same and matrix A is an identical matrix. Therefore, such cases do not meet Equations (2) and (3) and therefore are not identified as recalibration conditions.

Magnetometer bias can be determine by optimizing a suitable criterion, for example, by minimizing a mean quadratic error of magnetic map for the recalibration conditions, such as with a quadratic form in Equation (4):

$$Q = {\sum }_{k = 1}^{{K}_{loc}} {\sum }_{i = 1}^{{N}_{k}} {\vert {C}_{k i} ( {z}_{k i} - b ) - {F}_{k} \vert}^{2} \qquad ( 4 )$$

Several different variants of optimization techniques may be used for solving this optimization task such as, for example, gradient methods, coordinate descent algorithms, stochastic programming and others.

In an embodiment, an example of the iterative procedure may be as follows however other methods may also be employed.

As discussed above, steps 230-232 represent iterative determinations of magnetometer bias and consequent updates to the magnetic map. At step 230 magnetometer bias is determined based on magnetometer measurements, transformation matrixes, and magnetic map values for the recalibration conditions determined in the previous step 220. Then, at step 231 magnetic map for the recalibration conditions is updated using the magnetometer bias determined at step 230. Steps 230 and 231 are repeated until at step 232 it is decided that the iterative procedure (i.e., steps 230 and 231) has converged.

Differentiating Equation (4) and equaling to zero allows derivation of an estimate of the bias for iteration n as indicated in Equation (5):

$${b}_{n} = \frac{1}{N} {\sum }_{k = 1}^{{K}_{loc}} {\sum }_{i = 1}^{{N}_{k}} ( {z}_{k i} - {C}_{k i}^{T} {F}_{k} ( {b}_{n - 1} ) ) \qquad ( 5 )$$

In this equation, Fₖ(bₙ₋₁) is magnetic field map for recalibration condition k estimated on previous iteration n−1 using previous value of magnetometer bias bₙ₋₁. Update of the bias according to Equation (5) is performed at step 230.

Next, at step 231 the magnetic field map for recalibration conditions is updated using newly determined bias bₙ and obtain Fₖ(bₙ) using a suitable approach of building magnetic map. Then steps 230 and 231 are repeated for the next iteration, i.e., n+1, until bias estimate converges. It can be shown that the condition of bias convergence is the same as earlier mentioned for Equations (2) and (3).

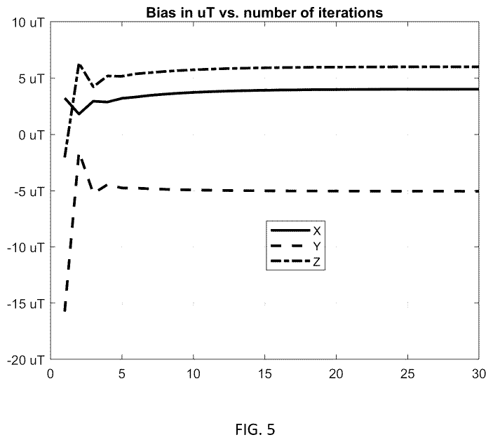

FIG. 5 shows an example of magnetometer bias determination using the described iterative procedure. The figure shows biases for X, Y, and Z axes of a magnetometer vs. number of iterations. It can be seen in FIG. 5 that a stationary solution for the biases may be obtained after less than 10 iterations. This may be used in a criterion at step 232 of completion of the iterations, for example, using difference between biases for two successive iterations |bₙ−bₙ₋₁| and comparing the difference with some small threshold, ε. If the difference is less than the threshold, i.e., |bₙ−bₙ₋₁|<ε then it is decided that the iterations may be completed

Once the magnetometer biases have been updated following the above techniques, the magnetic map may be rebuilt as indicated by step 240 of FIG. 2 using the more accurate magnetometer biases. As noted above, exemplary approaches for building the magnetic map are disclosed in U.S. Pat. No. 11,035,915 as incorporated above but it should be appreciated that any suitable map building technique may be employed.

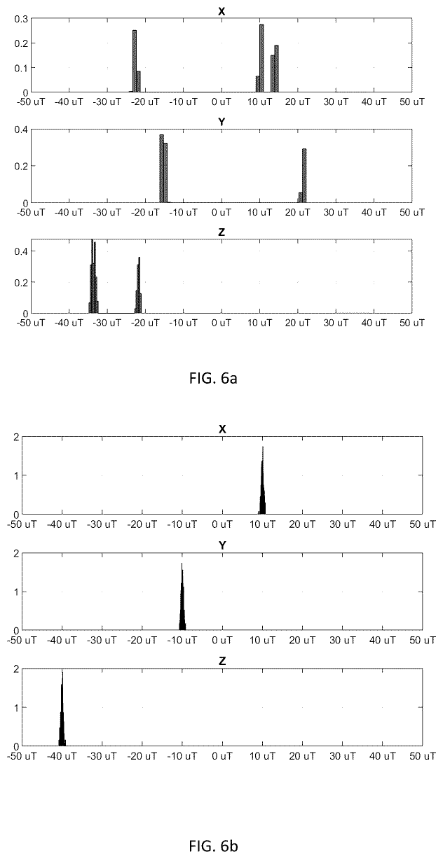

FIG. 6 illustrates effect of more accurate magnetometer biases determination by using the techniques of this disclosure in a simulated example. True values of magnetic field, specifically 10 uT, −10 uT, and −40 uT for axes X, Y, and Z respectively, were distorted by inaccurately calibrated initial magnetometer biases. FIG. 6a shows histograms of measurements of magnetic field transformed into navigation frame 320 for axes X, Y, and Z respectively, at step 210. As can be seen, the inaccurate initial biases determined at this step cause splitting of histograms, so that the estimated magnetic field is far from its true value.

In contrast, FIG. 6b shows histograms of measurements of magnetic field transformed into navigation frame 320 for axes X, Y, and Z respectively, in step 240 after application of the techniques of this disclosure. It can be seen that now the magnetic map that was rebuilt using determined biases accurately represents the true magnetic field.

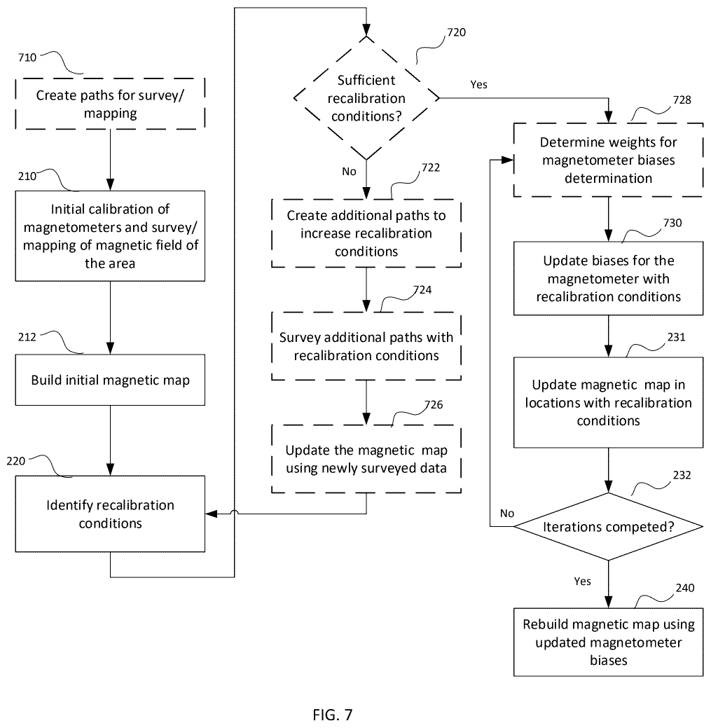

It should also be appreciated that various extensions and variations are within the scope of this disclosure. As one example, FIG. 7 shows examples of possible variants of the method schematically depicted in FIG. 2. These additional variants are shown as rectangles with dashed borders. These variants are discussed in the following materials.

As noted above, the techniques of this disclosure exploit recalibration conditions, such as locations at which two or more paths intersect. In some embodiments, for example, in a case of a regular survey, it may be possible, before the survey is conducted, to create survey paths that are configured to result in a desired number of recalibration conditions, for example, the paths may feature multiple intersections. The creation of paths may be fulfilled at step 710 of FIG. 7 that precedes step 210 of a basic method of FIG. 2.

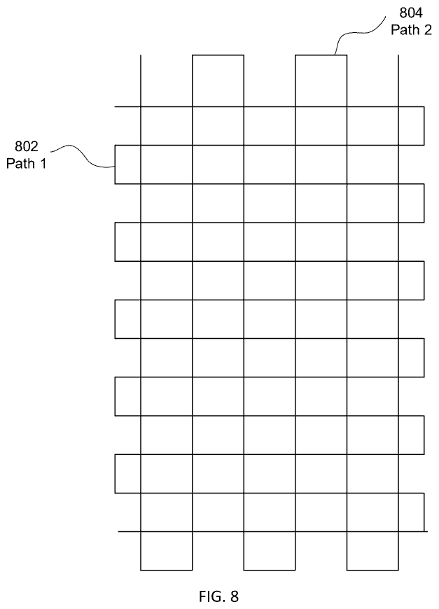

To help illustrate, FIG. 8 shows an example of survey paths. The paths created at step 710 may, for example, look like two rectangular meander lines 802 for path 1 and 804 for path 2. It is clear from the figure that these two lines intersect each other in multiple locations. These locations can serve as candidates for identification of recalibration conditions at step 212. Of course, the paths shown in FIG. 8 are only an example, and many other different shapes of paths can be used providing that the conditions on the recalibration conditions are met. This idea can be further improved by considering floor plan limitations, so that the created survey paths do not cross obstacles like walls. Several algorithms of computational geometry may be applied to prevent crossing the walls like, for example, a sweep line algorithm in combination with a collision detection algorithm to check if the line intersects with any obstacles. If an intersection is detected, the line can be adjusted to avoid the obstacle and continue sweeping the floor plan.

In some embodiments, before starting iterative determination of magnetometer biases and update of the magnetic map, one or more additional surveys can be performed if necessary. The necessity of the additional survey is determined at step 720 of FIG. 7 by checking if sufficient recalibration conditions are identified at step 220 that meet the characteristics explained above or not. The checking may be performed such as by using Equations (2) and (3) for convergence of iterative bias determination using definition of matrix A for these equations either from Equation (1) or Equation (8) for a weighted approach, which is described in further detail below.

If insufficient recalibration conditions are identified at step 720, then additional paths can be created at step 722. The additional paths may be created, for example, in such a way that they come through candidates of the recalibration conditions determined at step 212 and add more angle diversity. This may be implemented, for example, by randomly generating paths intersecting with existing paths in the recalibration conditions ensuring that they intersect at different angles and no lines are parallel. Equations (2) and (3) may be additionally checked to decide if a new path should be kept or rejected.

Then, a surveyor collects more data at least at locations meeting the recalibration conditions by following the additional paths, as indicated by step 724. At step 726, the magnetic map is updated using both previously collected data at step 211 and newly surveyed data at step 724. The updated magnetic map is assessed again at step 220 for identification of recalibration conditions. The recalibration conditions are again checked at step 720. If sufficient recalibration conditions meet the necessary characteristics, then the data for the recalibration conditions go to iterative determination of magnetometer bias.

Another modification within the scope of this disclosure is to employ weighted determination of the magnetometer biases as indicated by step 728. Generally, more accurate data is given increased weight and less accurate data is given decreased weight. As a result, better accuracy of bias determination may be achieved. As will be appreciated, there can be several weighted variants of quadratic form of Equation (4). For example, one of possible illustration is given as Equation (6):

$$Q = {\sum }_{k = 1}^{{K}_{loc}} {\sum }_{i = 1}^{{N}_{k}} \frac{1}{{σ}_{k i}^{2}} {( {C}_{k i} ( {z}_{k i} - b ) - {F}_{k} )}^{T} ( {C}_{k i} ( {z}_{k i} - b ) - {F}_{k} ) \qquad ( 6 )$$

In this equation, σₖᵢ⁻² is a weight associated with path i and recalibration condition k. Correspondingly, a weighted variant of estimate of bias for iteration n may be given as Equation (7):

$${b}_{n} = \frac{1}{S} {\sum }_{k = 1}^{{K}_{loc}} {\sum }_{i = 1}^{{N}_{k}} \frac{1}{{σ}_{ki}^{2}} ( {z}_{k i} - {C}_{k i}^{T} {F}_{k} ( {b}_{n - 1} ) ) \qquad ( 7 )$$

In this equation, normalizing factor

$$S = {\sum }_{k = 1}^{{K}_{loc}} {\sum }_{i = 1}^{{N}_{k}} \frac{1}{{σ}_{k i}^{2}} .$$

A weighted update of the bias according to Equation (7) is performed at step 730 (FIG. 7), which is a weighted variant of step 230 described above in relation with FIG. 2.

Matrix A as per Equations (2) and (3) as a measure of difference of orientation angels for the second condition of the recalibration conditions for the weighted variant may then be adapted as shown in Equation (8):

$$A = \frac{1}{S} {\sum }_{k = 1}^{{K}_{loc}} \frac{1}{{N}_{k} - 1} {\sum }_{i = 1}^{{N}_{k}} {{\sum }_{j = 1}^{{N}_{k}}}_{j \neq i} \frac{1}{{σ}_{k i}^{2}} {C}_{k i}^{T} {C}_{kj} \qquad ( 8 )$$

Weights σₖᵢ⁻² are determined at step 728 and may for example depend on one or any combination of the factors such as:
a number of paths associated with a recalibration condition, so that the more paths the higher weight,
magnetic field variation associated with a recalibration condition, so that the lower variations the higher weight,
angular diversity of the orientation angle measurements associated with a recalibration condition, so that the bigger diversity the higher weight,
uncertainty of orientation angles measurements at recalibration conditions, so that the lower uncertainty the higher weight,
uncertainty of magnetic field map at locations associated with a recalibration condition so that the lower uncertainty the higher weight.

The first factor, which is number of paths associated with a recalibration condition, contributes to bigger diversity as it gives a chance to get a significant difference of device orientation angels.

The second factor, i.e., magnetic field variation associated with a recalibration condition, allows deweighting for locations with significant variations of magnetic field, which otherwise may decrease accuracy of bias determination when the locations are within a threshold distance (refer to the discussion in relation with FIG. 4.) A level of magnetic field variation associated with the recalibration location may be assessed, for example, using initial magnetic map created at step 212 and updated at step 726 (FIG. 7) and estimating a gradient of magnetic field at the said location.

The third factor, angular diversity of the orientation angle measurements associated with the recalibration condition, has been discussed above regarding FIG. 4.

The fourth factor, i.e., uncertainty of orientation angles measurements at recalibration conditions, allows deweighting of less accurate angular measurements due to errors of inertial and other sensors used for angles determination.

The fifth factor, i.e., uncertainty of magnetic field map at locations associated with a recalibration condition, allows deweighting less accurate values of the magnetic map.

Yet other variants to the techniques of this disclosure involve the use of multiple survey devices that may be used concurrently or sequentially while surveying/mapping the area, for example, to expedite the survey or for another purpose. The techniques of this disclosure may be naturally generalized for such situations by applying the above approach for each magnetometer and finally rebuilding the magnetic map using the biases determined for all the magnetometers participated in the survey. The generalization can be explained with reference to FIG. 2 that earlier was used for description of one magnetometer case.

Steps 210 and 212 are almost the same as before with the modification that several devices (not just one) are initially calibrated and used for survey/mapping at step 210, and the initial magnetic map is built at step 212 using the data collected by several devices.

Iteration loop 230 and 231 includes updating of new magnetometer biases for each magnetometer at step 230. This can be, for example, implemented by applying equation (5) for non-weighted variant or (7) for weighted variant respectively to the data obtained from each device. Update of the magnetic field map at step 231 is performed using all the biases determined for each magnetometer at step 230.

After completion of the iterations for each magnetometer at step 232, the magnetic map of the area is rebuilt at step 240 using the determined biases of all the magnetometers participated in the survey/mapping.

Thus, this disclosure includes a method for building a magnetic map of an indoor area. The area comprises a plurality of positions and the magnetic map comprises Earth's magnetic field values for the positions. The method may involve building an initial magnetic map of the area by traversing the area with at least one platform having an associated magnetometer and obtaining Earth's magnetic field measurements with the magnetometer at determined positions and orientations of the at least one platform within the area, wherein the initial magnetic map is built based at least in part on an initial calibration of the magnetometer, identifying at least one recalibration condition for the area based at least in part on orientations and positions of the at least one platform, recalibrating the magnetometer based at least in part on the Earth's magnetic field measurements obtained for each recalibration condition, wherein biases for the magnetometer are updated and generating a rebuilt magnetic map for the area using the updated biases for the magnetometer.

In one aspect, recalibrating the magnetometer based at least in part on the Earth's magnetic field measurements obtained for the recalibration conditions may be provided iteratively by updating the biases at a current iteration using magnetic field map updated at a previous iteration for recalibration conditions and updating the magnetic field map for recalibration conditions using the magnetometer biases updated at a current iteration.

In one aspect, identifying the at least one recalibration condition for the area may include identifying all recalibration conditions that meet suitability criteria and wherein recalibrating the magnetometer comprises recalibrating based at least in part on the Earth's magnetic field measurements obtained for each recalibration condition.

In one aspect, the method may also involve traversing the area with at least one additional platform having an associated magnetometer and obtaining Earth's magnetic field measurements with the magnetometer at positions and orientations of the at least one additional platform within the area, wherein the initial magnetic map is built based at least in part on an initial calibration of the magnetometers of each platform and wherein the recalibration is performed for the magnetometers of the platforms and wherein the rebuilt magnetic map is generated using the updated biases for the magnetometers of each platform.

In one aspect, identifying the at least one recalibration condition may involve determining a threshold distance for positions of the at least one platform at which Earth's magnetic field measurements were obtained. Further, identifying the at least one recalibration condition may involve determining a threshold angular deviation in orientations of the at least one platform at which the Earth's magnetic field measurements were obtained at positions within the threshold distance.

In one aspect, the method may also involve a weighted determination of the magnetometer biases. The weighted update of the magnetometer biases may be based on at least one of i) a number of paths associated with a recalibration condition, ii) magnetic field variation associated with a recalibration condition, iii) angular diversity of orientation angle measurements associated with a recalibration condition, iv) uncertainty of orientation angle measurements at recalibration conditions and v) uncertainty of magnetic field map at locations associated with a recalibration condition.

In one aspect, the method may also involve creating a first path for traversing the area by the at least one platform. At least one additional path for traversing the area by the at least one platform may be created based at least in part on a number of identified recalibration conditions for the area meeting criteria based at least in part on orientation and position of the at least one platform after traversing the first path. The area may be traversed with at least one platform by traversing the at least one additional path with the at least one platform, identifying a new recalibration condition for the at least one additional path, and recalibrating the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

In one aspect, the initial calibration of the magnetometer may be performed after the Earth's magnetic field measurements are obtained.

This disclosure also includes a system for building a magnetic map of an indoor area, wherein the area comprises a plurality of positions and wherein the magnetic map comprises Earth's magnetic field values for the positions. The system may have at least one platform having an associated magnetometer for traversing the area to obtain Earth's magnetic field measurements at determined positions and orientations of the at least one platform within the area, remote processing resources configured to: i) build an initial magnetic map of the area, wherein the initial magnetic map is built based at least in part on an initial calibration of the magnetometer, ii) identify at least one recalibration condition for the area based at least in part on orientations and positions of the at least one platform, iii) recalibrate the magnetometer based at least in part on the Earth's magnetic field measurements obtained for each recalibration condition, wherein biases for the magnetometer are updated and iv) generate a rebuilt magnetic map for the area using the updated biases for the magnetometer.

In one aspect, the remote processing resources may be further configured to create a first path for traversing the area by the at least one platform. The remote processing resources may be further configured to create at least one additional path for traversing the area by the at least one platform based at least in part on a number of identified recalibration conditions for the area meeting criteria based at least in part on orientation and position of the at least one platform after traversing the first path by the at least one platform. The remote processing resources may also be further configured to select a new recalibration condition for the at least one additional path after traversing the at least one additional path with the at least one platform, and recalibrate the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

In one aspect, the remote processing resources may be further configured to perform the initial calibration of the magnetometer after the Earth's magnetic field measurements are obtained.

In one aspect, the determined positions and orientations of the at least one platform within the area are determined at least in part by the remote processing resources.

This disclosure also includes a server for building a magnetic map of an indoor area, wherein the area comprises a plurality of positions and wherein the magnetic map comprises Earth's magnetic field values for the positions. The server may have processing resources configured to: a) build an initial magnetic map of the area from Earth's magnetic field measurements obtained from at least one platform having an associated magnetometer that traverses the area at determined positions and orientations, wherein the initial magnetic map is built based at least in part on an initial calibration of the magnetometer, b) identify at least one recalibration condition for the area based at least in part on orientations and positions of the at least one platform, c) recalibrate the magnetometer based at least in part on the Earth's magnetic field measurements obtained for each recalibration condition to update biases for the magnetometer and d) generate a rebuilt magnetic map for the area using the updated biases for the magnetometer.

In one aspect, the server may be further configured to create a first path for traversing the area by the at least one platform. The server may also be further configured to create at least one additional path for traversing the area by the at least one platform based at least in part on a number of selected recalibration conditions for the area meeting criteria based at least in part on orientation and position of the at least one platform after traversing the first path by the at least one platform. The server may also be configured to select a new recalibration condition for the at least one additional path after traversing the at least one additional path with the at least one platform, and recalibrate the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

In one aspect, the server may be further configured to perform the initial calibration of the magnetometer after the Earth's magnetic field measurements are obtained.

In one aspect, the determined positions and orientations of the at least one platform within the area may be determined at least in part by the server.

From the above, it will be appreciated that a new approach to survey/mapping of magnetic field indoors is detailed in this disclosure to provide magnetometer recalibration after survey that allows limitations of achievable magnetometer calibration accuracy indoors to be overcome. Initial calibration of magnetometers can be simplified, which is beneficial for expediting the survey. In some cases, the initial calibration, for example, can be even substituted with using of previously saved magnetometer biases. Repeatable calibration of the magnetometer may be excluded from survey to also simplify the process of mapping. As a result, survey/mapping of magnetic field in an indoor environment can be performed more quickly and more accurately.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the present invention.

What is claimed is:

1. A method for building a magnetic map of an indoor area, wherein the area comprises a plurality of positions and wherein the magnetic map comprises Earth's magnetic field values for the positions, the method comprising:
a) building an initial magnetic map of the area by traversing the area with at least one platform having an associated magnetometer and obtaining Earth's magnetic field measurements with the magnetometer at determined positions and orientations of the at least one platform within the area, wherein the initial magnetic map is built based at least in part on an initial calibration of the magnetometer;
b) identifying at least one recalibration condition for the area based at least in part on orientations and positions of the at least one platform;
c) recalibrating the magnetometer based at least in part on the Earth's magnetic field measurements obtained for each recalibration condition, wherein biases for the magnetometer are updated; and
d) generating a rebuilt magnetic map for the area using the updated biases for the magnetometer.

2. The method of claim 1, wherein recalibrating the magnetometer based at least in part on the Earth's magnetic field measurements obtained for the recalibration conditions is provided iteratively by updating the biases at a current iteration using magnetic field map updated at a previous iteration for recalibration conditions and updating the magnetic field map for recalibration conditions using the magnetometer biases updated at current iteration.

3. The method of claim 1, wherein identifying the at least one recalibration condition for the area comprises identifying all recalibration conditions that meet suitability criteria and wherein recalibrating the magnetometer comprises recalibrating based at least in part on the Earth's magnetic field measurements obtained for each recalibration condition.

4. The method of claim 1, further comprising traversing the area with at least one additional platform having an associated magnetometer and obtaining Earth's magnetic field measurements with the magnetometer at positions and orientations of the at least one additional platform within the area, wherein the initial magnetic map is built based at least in part on an initial calibration of the magnetometers of the platforms and wherein the recalibration is performed for the magnetometers of each platform and wherein the rebuilt magnetic map is generated using the updated biases for the magnetometers of each platform.

5. The method of claim 1, wherein identifying the at least one recalibration condition comprises determining a threshold distance for positions of the at least one platform at which Earth's magnetic field measurements were obtained.

6. The method of claim 5, wherein identifying the at least one recalibration condition comprises determining a threshold angular deviation in orientations of the at least one platform at which the Earth's magnetic field measurements were obtained at positions within the threshold distance.

7. The method of claim 1, further comprising a weighted determination of the magnetometer biases.

8. The method of claim 7, wherein the weighted update of the magnetometer biases is based on at least one of:
i) a number of paths associated with a recalibration condition;
ii) magnetic field variation associated with a recalibration condition;
iii) angular diversity of orientation angle measurements associated with a recalibration condition;
iv) uncertainty of orientation angle measurements at recalibration conditions; and
v) uncertainty of magnetic field map at locations associated with a recalibration condition.

9. The method of claim 1, further comprising creating a first path for traversing the area by the at least one platform.

10. The method of claim 9, further comprising creating at least one additional path for traversing the area by the at least one platform based at least in part on a number of identified recalibration conditions for the area meeting criteria based at least in part on orientation and position of the at least one platform after traversing the first path.

11. The method of claim 10, further comprising traversing the area with at least one platform by traversing the at least one additional path with the at least one platform, identifying a new recalibration condition for the at least one additional path, and recalibrating the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

12. The method of claim 1, wherein the initial calibration of the magnetometer is performed after the Earth's magnetic field measurements are obtained.

13. A system for building a magnetic map of an indoor area, wherein the area comprises a plurality of positions and wherein the magnetic map comprises Earth's magnetic field values for the positions, the system comprising:
a) at least one platform having an associated magnetometer for traversing the area to obtain Earth's magnetic field measurements at determined positions and orientations of the at least one platform within the area;
b) remote processing resources configured to:
i) build an initial magnetic map of the area, wherein the initial magnetic map is built based at least in part on an initial calibration of the magnetometer;
ii) identify at least one recalibration condition for the area based at least in part on orientations and positions of the at least one platform;
iii) recalibrate the magnetometer based at least in part on the Earth's magnetic field measurements obtained for each recalibration condition, wherein biases for the magnetometer are updated; and
iv) generate a rebuilt magnetic map for the area using the updated biases for the magnetometer.

14. The system of claim 12, wherein the remote processing resources are further configured to create a first path for traversing the area by the at least one platform.

15. The system of claim 14, wherein the remote processing resources are further configured to create at least one additional path for traversing the area by the at least one platform based at least in part on a number of identified recalibration conditions for the area meeting criteria based at least in part on orientation and position of the at least one platform after traversing the first path by the at least one platform.

16. The system of claim 15, wherein the remote processing resources are further configured to select a new recalibration condition for the at least one additional path after traversing the at least one additional path with the at least one platform, and recalibrate the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

17. The system of claim 13, wherein the remote processing resources are further configured to perform the initial calibration of the magnetometer after the Earth's magnetic field measurements are obtained.

18. The system of claim 13, wherein the determined positions and orientations of the at least one platform within the area are determined at least in part by the remote processing resources.

19. A server for building a magnetic map of an indoor area, wherein the area comprises a plurality of positions and wherein the magnetic map comprises Earth's magnetic field values for the positions, the server having processing resources configured to:
a) build an initial magnetic map of the area from Earth's magnetic field measurements obtained from at least one platform having an associated magnetometer that traverses the area at determined positions and orientations, wherein the initial magnetic map is built based at least in part on an initial calibration of the magnetometer;
b) identify at least one recalibration condition for the area based at least in part on orientations and positions of the at least one platform;
c) recalibrate the magnetometer based at least in part on the Earth's magnetic field measurements obtained for each recalibration condition to update biases for the magnetometer; and
d) generate a rebuilt magnetic map for the area using the updated biases for the magnetometer.

20. The system of claim 19, wherein the server is further configured to create a first path for traversing the area by the at least one platform.

21. The system of claim 20, wherein the server is further configured to create at least one additional path for traversing the area by the at least one platform based at least in part on a number selected recalibration conditions for the area meeting criteria based at least in part on orientation and position of the at least one platform after traversing the first path by the at least one platform.

22. The system of claim 21, wherein the server is further configured to select a new recalibration condition for the at least one additional path after traversing the at least one additional path with the at least one platform, and recalibrate the magnetometer based at least in part on the Earth's magnetic field measurements obtained for the new recalibration condition to update biases for the magnetometer for each recalibration condition, wherein generating the rebuilt magnetic map for the area uses the updated biases for the magnetometer.

23. The system of claim 19, wherein the server is further configured to perform the initial calibration of the magnetometer after the Earth's magnetic field measurements are obtained.

24. The system of claim 19, wherein the determined positions and orientations of the at least one platform within the area are determined at least in part by the server.
